(19) United States
(12) Patent Application Publication
(10) Pub. No.: US 2002/0098600 A1
(43) Pub. Date: Jul. 25, 2002

(54) System and method for status settings of semiconductor equipment with multi chambers

(75) Inventors: Jack Yao, Lin-Pien Hsiang (TW); Ping-Chung Chung, Hsin-Chu (TW); Wei-Hsu Wang, Lin-Yuan (TW); Wei-Hao Lee, Taichung City (TW); Chien-Feng Chen, Kaohsiung City (TW); Feng-Chi Chung, Miao-Li (TW); Kuen-Chu Chen, Hsin-Chu (TW); Ming-Che Ho, Hsin-Chu City (TW)

Correspondence Address: LOWE HAUPTMAN GILMAN & BERNER, LLP, Suite 310, 1700 Diagonal Road, Alexandria, VA, 22314, US

(73) Assignee: United Microelectronics Corp., Taiwan (CN)

(21) Appl. No.: 09/941,786

(22) Filed: Aug. 30, 2001

Related U.S. Application Data
(62) Division of application No. 09/766,643, filed on Jan. 23, 2001.

(51) Int. Cl. H01L 21/66

(52) U.S. Cl. 438/14

(57) ABSTRACT

In the present invention, setting apparatus for semiconductor equipment with multitude of chambers comprises a plurality of input devices coupled to a controlling system of the semiconductor equipment. The input devices are used for setting a maintain status of said chambers whereby said chambers can be available for a test process. A method for setting a plurality of statuses for a plurality of chambers in semiconductor equipment comprises setting a plurality of maintain statuses for the chambers and executing a plurality of test process in the chambers in the maintain statuses. To be specific, the setting step can simultaneously set an on-line status for each the chamber and the maintain status for other the chamber.

### BACKGROUND OF THE INVENTION

1. Field of the Invention

The invention relates to a system and method for status settings of semiconductor equipment, and more particularly to a system and method for status settings of semiconductor equipment with multitude of chambers.

2. Description of the Prior Art

For some semiconductor manufacture equipment with multi-chambers, it is only provided two statuses for each chamber: on-line and off-line. Typically, an operator can assign each wafer in a cassette to be moved into the specific chambers in on-line status according to a specific recipe, such as product recipe. Moreover, an engineer also can take repair or periodic maintain for chambers in use of in their off-line statuses.

Shown in FIG. 1 is a flow chart for a conventional operation of semiconductor manufacture equipment with multi-chamber type. First, wafers are moved into a buffer station by a robot and the specific chambers need to be confirmed to be in on-line status (step 110). The wafers can't be moved into the chambers in case the chambers are in off-line status (step 111). Next, the wafers are moved into the specific chambers for processing according to the assigned recipes (step 112). If one or more of the chambers are in need of running dummy test after repairing or running period maintain, it is necessary for the chambers to wait the whole wafers in the normal chambers to be accomplished in the process (step 113). Then the normal chambers are set to be in off-line status (step 114) for running dummy tests of the “abnormal” chambers(step 115). The dummy tests are accomplished without abnormality (step 116) and then the repaired or maintained chambers can continuously work.

However, there are some liabilities for semiconductor manufacture and production with such an operation mode. First, the product run (normal wafer process) and the dummy run can't be executed at same time, so that results increase on down time of the chambers. The down time for a normal chamber means the period that the chamber isn't executed production, while for a chamber after repairing or periodic maintain means the consumption period that the chamber is recovered from abnormality or maintain. Second, when the normal chambers are set in off-line status for a long time by reason of dummy tests and doesn't automatically execute cleaning particles according to a cleaning recipe, that may result in decline in wafers qualities of coming manufacture process. Third, though the chambers may be executed independently in use of parallel lot mode offered by the semiconductor manufacture equipment, the wafers production is at the risk of wrong settings for the product recipes.

### SUMMARY OF THE INVENTION

It is an object of the present invention to provide status settings apparatus and a system for setting statuses for semiconductor equipment with multitude of chambers. In the present invention, a maintain status can be set through the setting apparatus and engineers can do dummy tests for the chamber in the maintain status.

It is another object of the present invention to provide a system and method for setting statuses for semiconductor equipment with multitude of chambers. Engineers do dummy tests for the individual chamber with setting the maintain status, whereby can reduce the downtime of other chamber.

It is a further object of the present invention to provide a system and method for setting statuses for chambers in semiconductor equipment. The chambers can be executed with specific recipes according to their set statuses.

In the present invention, setting apparatus for semiconductor equipment with multitude of chambers comprises a plurality of input devices coupled to a controlling system of the semiconductor equipment. The input devices are used for setting a maintain status of the chambers whereby the chambers can be available for a test process. A method for setting a plurality of statuses for a plurality of chambers in semiconductor equipment comprises setting a plurality of maintain statuses for the chambers and executing a plurality of test process in the chambers in the maintain statuses. To be specific, the setting step can simultaneously set an on-line status for each the chamber and the maintain status for other the chamber.

### BRIEF DESCRIPTION OF THE DRAWINGS

A better understanding of the invention may be derived by reading the following detailed description with reference to the accompanying drawing wherein

FIG. 1 is an operation flow chart of manufacture equipment with multi-chamber type in accordance with a prior art; and

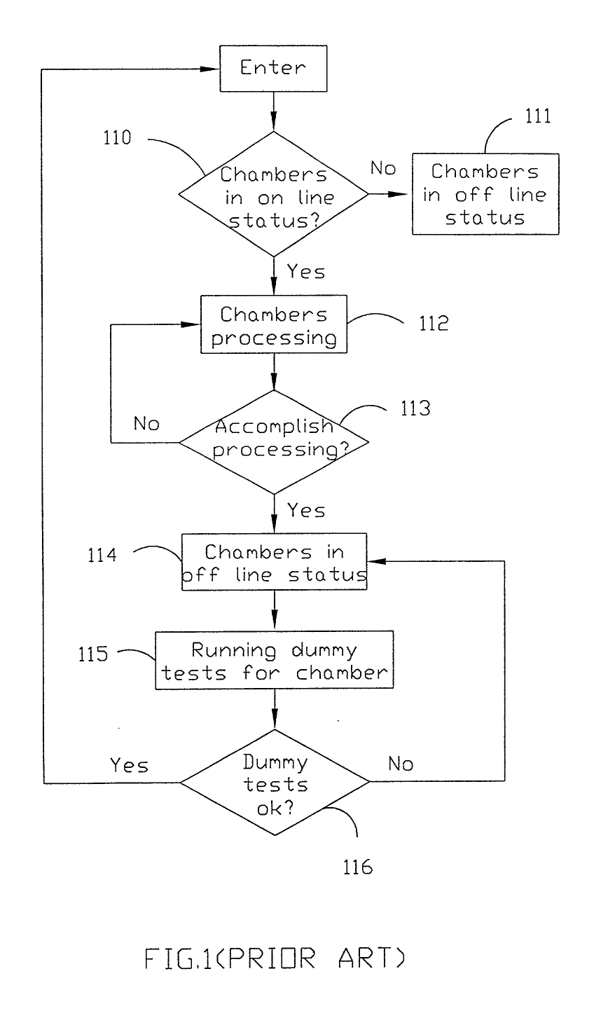

FIG. 2 is an operation flow chart of manufacture equipment with multi-chamber type in accordance with the present invention.

### DESCRIPTION OF THE PREFERRED EMBODIMENT

While the invention is described in terms of a single preferred embodiment, those skilled in the art will recognize that many steps described below can be altered without departing from the spirit and scope of the invention.

In the present invention, a system for setting a plurality of statuses for a plurality of chambers in semiconductor equipment comprises a controlling system configuring a plurality of settings for the chambers. A plurality of input devices are coupled to the controlling system. The input devices are used for inputting the settings and comprise for setting a maintain status for each chamber. A plurality of indicators are coupled to the controlling system, which are used for displaying the settings and each the maintain status. A method for setting a plurality of statuses for a plurality of chambers in semiconductor equipment comprises setting a plurality of maintain statuses for the chambers and executing a plurality of test process in the chambers in the maintain statuses. To be specific, the setting step can simultaneously set an on-line status for each said chamber and said maintain status for other said chamber.

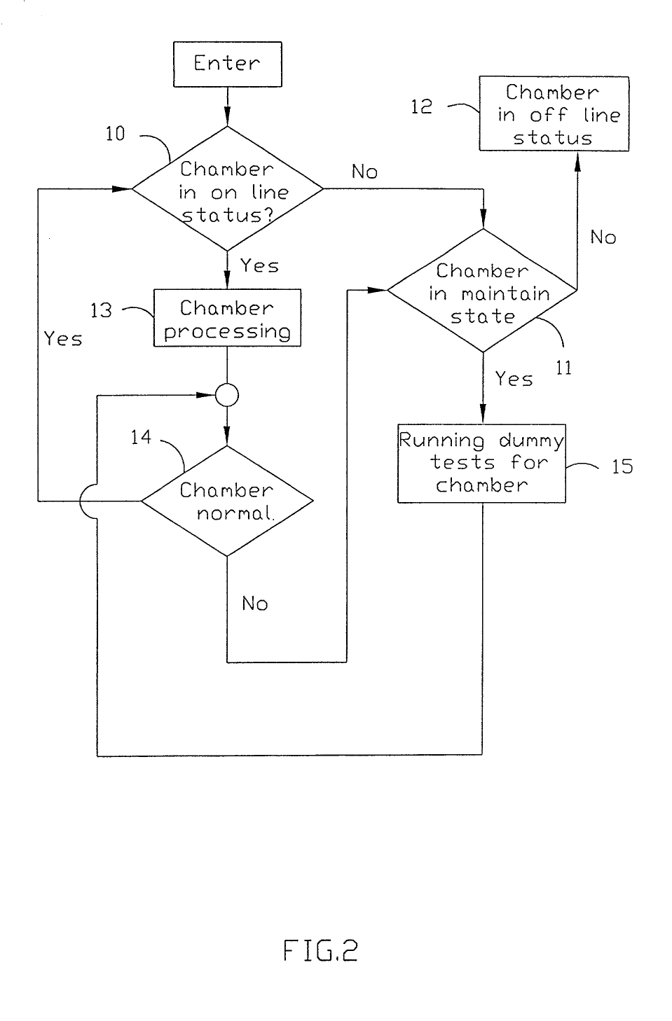

Referring to FIG. 2, similarly, wafers are moved into a buffer station by a robot and the chambers need to be confirmed to be in online status (step 10). Typically, the wafers of formal product can't be moved into the chambers in case the chambers are in off-line status (step 12). Next, the wafers are moved into the specific chambers and run according to the assigned recipes (step 13). Besides, maintain status setting for a chamber is provided in the present invention, which is used for dummy tests of the chamber and different from the off-line status. When a chamber is set in maintain status, it still can be executed running according to a specific recipe different from a product recipe. A chamber set in maintain status (step 11) means that operator or engineer can take repair, periodic maintain (step 15), or execute dummy run for the chamber. It is appreciated when each chamber is normal in on-line status(step 14) and then the next wafers in the buffer station can continuously moved into.

Furthermore, on a displayed screen of a controller coupled to the multi-chamber manufacture equipment, the maintain status of the chamber can be set by controlling buttons and shown as an indicator with color different from ones represented the on-line and off-line status. For example, the indicator of chamber shown in blue means to be in on-line status, in white to be in off-line status, and in yellow to be in maintain status. Furthermore, the recipes are designed and divided into various groups in use of suitable status. For example, a chamber in on-line status can be executed according to the product recipe of an on-line recipes group, and one in maintain status can be executed only according to the monitor recipe of a maintain recipes group. It is advantageous to preventing from running a chamber with a recipe not coincided with a suitable status and separating wafers in production from ones in test or dummy run. Furthermore, the present invention also can reduce the consumption of down time. These chambers in the manufacture equipment can be executed independent of each another in different status.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. Status setting apparatus for semiconductor equipment with multitude of chambers, said apparatus comprising:
a plurality of input devices coupled to a controlling system of said semiconductor equipment, said input devices used for setting a maintain status of said chambers whereby said chambers can be available for a dummy test.

2. The apparatus of claim 1, wherein said input devices further are used for setting an on-line status and an off-line status.

3. The apparatus of claim 1, wherein said input devices comprise having a plurality of indicators for showing statuses of said chambers according to said status settings from said input devices.

4. The apparatus of claim 1, wherein said input devices comprise a plurality of buttons coupled to said controlling system of said semiconductor equipment.

5. A system for setting a plurality of statuses for a plurality of chambers in semiconductor equipment, said system comprising:
a controlling system configuring a plurality of status settings for said chambers;
a plurality of input devices coupled to said controlling system, said input devices for inputting said settings and used for setting a maintain status for each said chamber; and
a plurality of indicators coupled to said controlling system, said indicators used for displaying said settings and each said maintain status.

6. The system of claim 5, wherein said input devices comprise a plurality of buttons coupled to said controlling system.

7. A method for setting a plurality of statuses for a plurality of chambers in semiconductor equipment, said method comprising:
setting a maintain status for each said chamber; and
executing a plurality of dummy tests in said chambers in said maintain statuses.

8. The method according to claim 7 further comprising displaying said maintain statuses on a displaying panel coupled to said semiconductor equipment.

9. The method according to claim 7, wherein said setting step further comprises simultaneously setting an on-line status for each said chamber.

10. The method according to claim 7, wherein said setting step further comprises setting an off-line status for each said chamber.
